(19) United States
(12) Patent Application Publication
(10) Pub. No.: US 2008/0160744 A1
(43) Pub. Date: Jul. 3, 2008

(54) METHOD FOR FABRICATING SEMICONDUCTOR DEVICE AND IMPROVING THIN FILM UNIFORMITY

(75) Inventors: Chia-Po Lin, Taoyuan County (TW); Chien-Lung Chu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: POWERCHIP SEMICONDUCTOR CORP., Hsinchu (TW)

(21) Appl. No.: 11/946,032

(22) Filed: Nov. 27, 2007

(30) Foreign Application Priority Data
Jan. 2, 2007 (TW) 96100078

(51) Int. Cl. H01L 21/28

(52) U.S. Cl. 438/591; 257/E21.179

(57) ABSTRACT

A substrate including a memory cell region and a peripheral circuit region is provided. A first dielectric layer, a first conductive layer and a mask layer are formed on the substrate. Isolation structures are formed, and the isolation structures in the memory cell region are denser than that in the peripheral circuit region. A protective layer is formed on the substrate in the second region. The mask layer in the first region is removed. A second conductive layer is formed on the substrate, wherein the protective layer has an etching selectivity the same to that of the second conductive layer. Portion of the second conductive layer and the protective layer are removed by using the isolation structures as stop layer. Portion of the isolation structures and the mask layer in the peripheral circuit region are removed. A second dielectric layer and a third conductive layer are formed on the substrate.

### CROSS-REFERENCE TO RELATED APPLICATION

This application claims the priority benefit of Taiwan application serial no. 96100078, filed on Jan. 2, 2007. The entirety of the above-mentioned patent application is hereby incorporated by reference herein and made a part of this specification.

### BACKGROUND OF THE INVENTION

1. Field of the Invention

The present invention relates to a method for fabricating an integrated circuit, and more particularly, to a method for fabricating a semiconductor device and improving thin film uniformity.

2. Description of Related Art

As the functions of computer and electronic products continue to advance, the complexity of application circuits has increased to improve device speed and functions, and produce more compact and lighter electronic devices since the level of integration for devices has to increase to facilitate the integration of more devices having different functions into a single chip.

In general, to accommodate different device designs, the pattern density of different isolation structure in different region of the substrate has to be varied accordingly. Take memory devices as an example. The pattern density of an isolation structure in a memory cell region is greater than that in the peripheral circuit region. Hence, the uniformity of planarization for the thin film over the surface of a wafer is not guaranteed.

FIG. 1A through FIG. 1C schematically illustrates the conventional steps for fabricating a memory device and a logic device. In FIG. 1A, a substrate 100 includes a memory cell region 103 and a peripheral circuit region 105. An oxide layer 110 and a conductive layer 120 are disposed on the substrate 100. An isolation structure 130 is disposed in the conductive layer 120, the oxide layer 110 and the substrate 100. Further, the surface of the isolation structure 130 is higher than that of the conductive layer 120. A conformal conductive layer 140 is formed over the substrate 100, covering the memory cell region 103 and the peripheral circuit region 105. Since the pattern/layout density of the isolation structure for the peripheral circuit 105 is comparatively smaller, the distribution of pattern is thus relatively sparse. Therefore, a concave shape is formed on the conductive layer 140 disposed on the conductive layer 120 in the peripheral circuit 105.

In FIG. 1B, a chemical mechanical polishing process is performed to planarize the conductive layer 140. After the planarization process, a concave disc 143 and a sharp corner 145 are formed on the conductive layer 140 in the peripheral circuit region 105 because the conductive layer 140 was concave. The concavity of the conductive layer 140 reduces the efficiency of the chemical mechanical polishing process and adversely affects the uniformity of the thin film over the surface of a wafer.

In FIG. 1C, a portion of the isolation structure 130 is removed. Further, an inter-gate dielectric layer 150 and a conductive layer 160 are formed sequentially. As shown in FIG. 1C, the subsequently formed inter-gate dielectric layer 150 and conductive layer 160 take on the profile of the concave disc 143 and the sharp corner 145 in the peripheral circuit region 105. The profile having varying height reduces the electrical performance of devices in the peripheral circuit region 105 and results in difficulties for fabricating the subsequent layers.

### SUMMARY OF THE INVENTION

Accordingly, the present invention provides a method for fabricating a semiconductor device that improves the uniformity of the thin film over the surface of a wafer.

Further, the present invention also provides a simple and effective method for improving the uniformity of the thin film over the surface of a wafer that provides a better control for the overall fabrication process.

The method for fabricating a semiconductor device according to the present invention includes the following steps. First, a substrate that includes a memory cell region and a peripheral circuit region is provided. A first dielectric layer, a first conductive layer and a mask layer are formed on the substrate. Further, a plurality of isolation structures are formed in the mask layer, the first conductive layer, the first dielectric layer and the substrate. Herein, the isolation structures in the memory cell region are denser than that in the peripheral circuit region. Then, a protective layer is formed over the substrate in the peripheral circuit region. Next, the mask layer in the memory cell region is removed and a second conductive layer is formed on the substrate. The protective layer and the conductive layer have approximately the same etching selectivity. Afterward, a portion of the second conductive layer and a portion of the protective layer are removed using the isolation structures as a stop layer. Thereafter, portions of the isolation structures and the mask layer in the peripheral region are removed. Subsequently, a second dielectric layer and a third conductive layer are formed over the substrate in sequence.

According to the embodiment of the present invention, the method for forming the protective layer over the substrate in the peripheral region includes the following steps. First, a conformal protective material layer is formed over the substrate. Next, a patterned photoresist layer is formed on the protective material layer in the peripheral circuit region. Afterward, the protective material layer in the memory cell region is removed using the patterned photoresist layer as a mask.

According to the embodiment of the present invention, the mask layer in the memory cell region is removed using the patterned photoresist layer as a mask.

According to the embodiment of the present invention, the material of the protective layer and the second conductive layer includes polysilicon.

According to the present embodiment of the present invention, the method for removing a portion of the second conductive layer and the protective layer using the isolation structures as a stop layer includes a chemical mechanical polishing process (CMP).

According to the embodiment of the present invention, the method for removing portions of the isolation structures includes a wet etching process.

According to the embodiment of the present invention, the second dielectric layer includes silicon oxide-silicon nitride-silicon oxide.

According to the embodiment of the present invention, the material of the first dielectric layer includes silicon oxide.

According to the embodiment of the present invention, the material of the mask layer includes silicon nitride.

According to the embodiment of the present invention, the material of the third conductive layer includes doped polysilicon.

According to the embodiment of the present invention, after a portion of the second conductive layer and the protective layer is removed, the surface of the first conductive layer in the peripheral circuit region is maintained to be flat.

The present invention provides a method for improving the thin film uniformity suitable for a substrate having a first region and a second region, wherein a dielectric layer, a first conductive layer and a mask layer are formed on the substrate, a plurality of isolation structures are formed in the mask layer, the dielectric layer and the substrate, and the isolation structures in the first region are denser than that in the second region. The method for improving the thin film uniformity according to the present invention includes the following steps. First, a protective layer is formed over the substrate. Next, the protective layer and the mask layer in the first region are removed. Afterward, a second conductive layer is formed over the substrate. The second conductive layer and the protective layer have approximately the same etching selectivity. A portion of the second conductive layer and the protective layer are removed using the isolation structures as a stop layer. Thereafter, portions of the isolation structures are removed. Subsequently, the mask layer in the second region is removed. Herein, the surface of the first conductive layer in the second region is maintained to be flat.

According to the embodiment of the present invention, the method for removing the protective layer in the first region and the mask layer includes the following steps. First, a patterned photoresist layer is formed on the protective layer in the second region. Next, the protective layer and the mask layer in the first region are removed using the patterned photoresist layer as a mask.

According to the embodiment of the present invention, the material of the protective layer and the second conductive layer includes polysilicon.

According to the present embodiment of the present invention, the method for removing a portion of the second conductive layer and the protective layer using the isolation structure as a stop layer includes a chemical mechanical polishing process (CMP).

According to the embodiment of the present invention, the method for removing portions of the isolation structures includes a wet etching process.

According to the embodiment of the present invention, the material of the dielectric layer includes silicon oxide.

According to the embodiment of the present invention, the material of the mask layer includes silicon nitride.

According to the present invention, the protective layer in the second region is formed to cover the mask layer in the second region and the first conductive layer prior to the formation of the second conductive layer, which maintains the uniformity of the layers fabricated subsequently and prevents the formation of a concave disc. As a result, the present invention not only improves the uniformity of the thin film over the surface of a wafer, which is beneficial to the fabrication of subsequent layers, but also the electrical performance of the devices in the second region.

In order to make the above and other objects, features and advantages of the present invention more comprehensible, several embodiments accompanied with figures are described in detail below.

### BRIEF DESCRIPTION OF THE DRAWINGS

FIG. 1A through FIG. 1C schematically illustrate the conventional steps for fabricating a memory device and a logic device.

FIG. 2A through FIG. 2F schematically illustrate the steps for fabricating a semiconductor device according to one embodiment of the present invention.

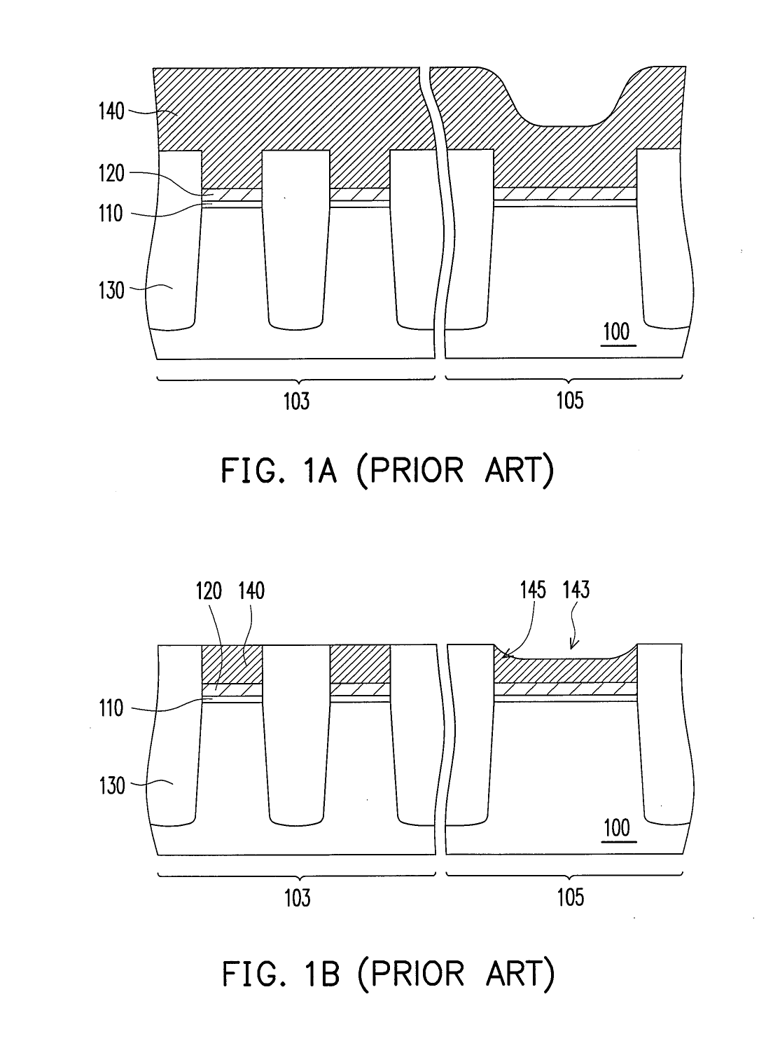

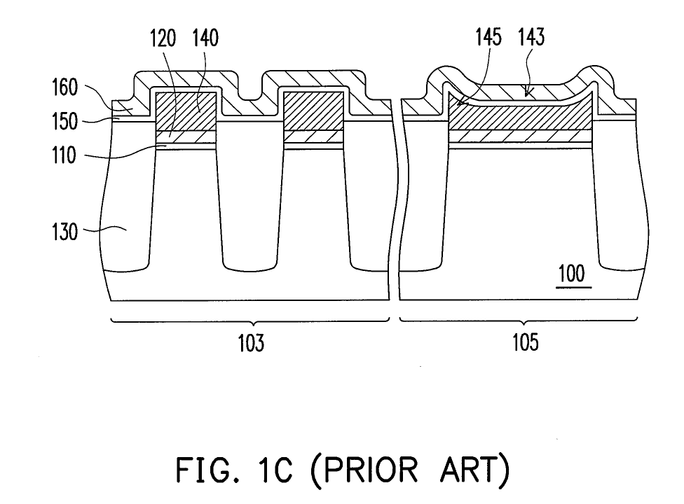

### DESCRIPTION OF EMBODIMENTS

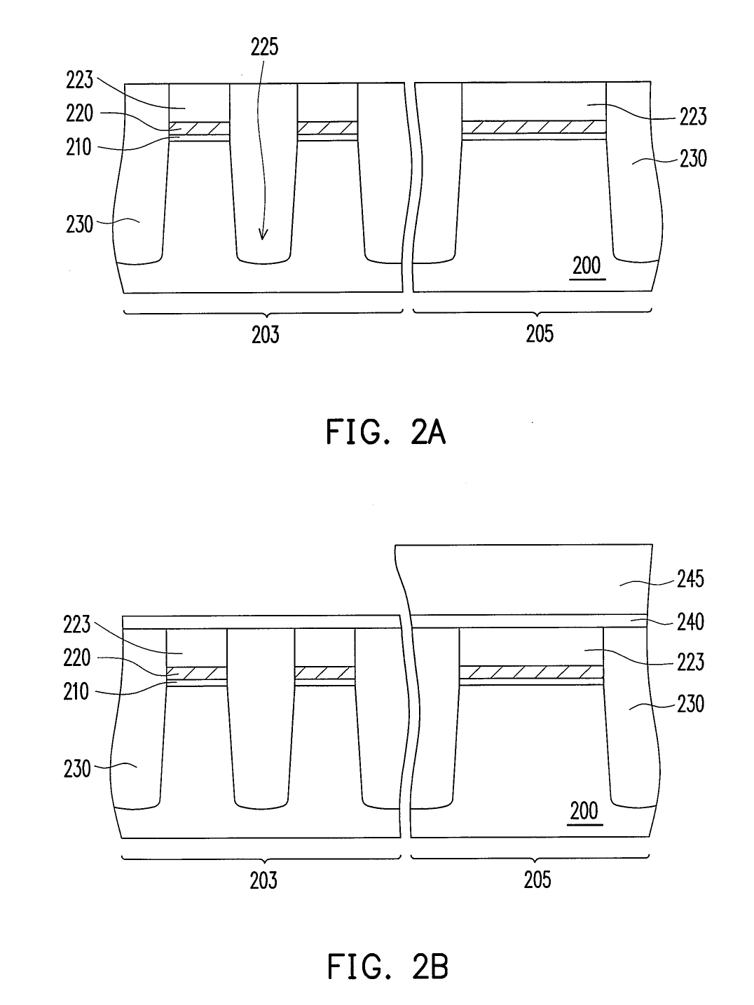

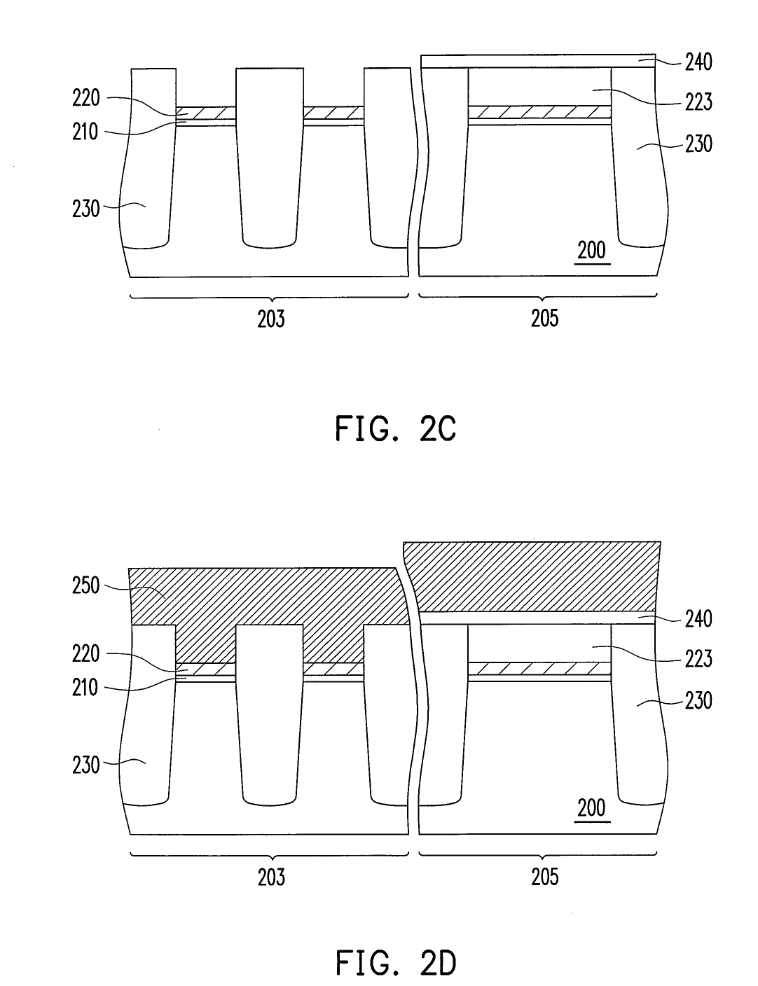

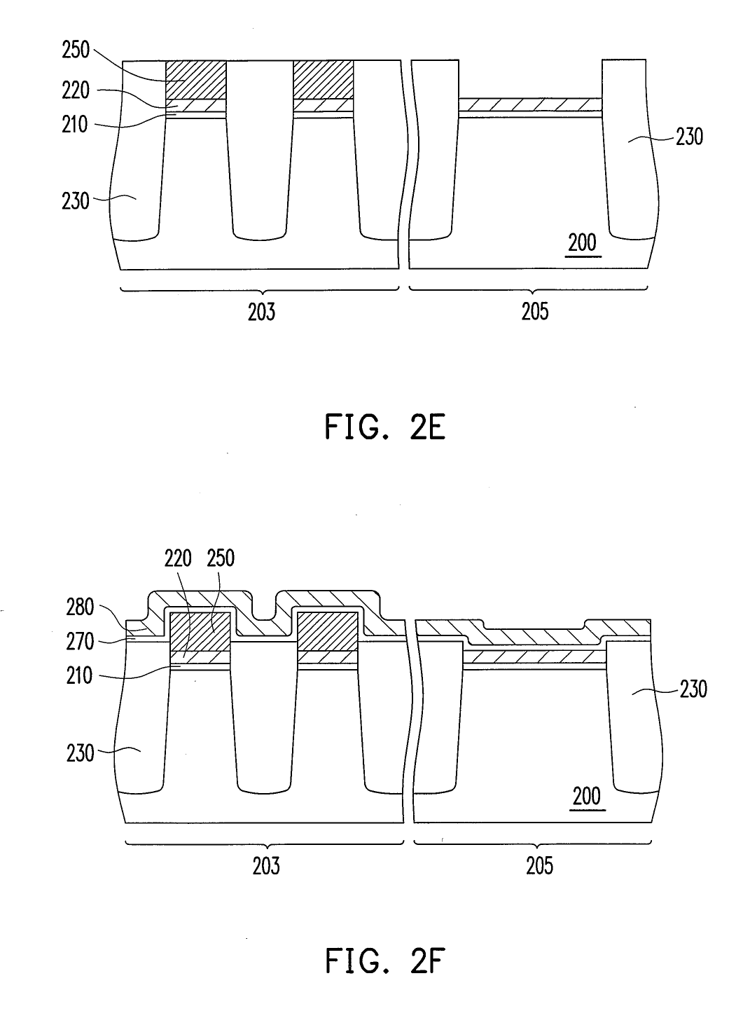

FIGS. 2A through 2F schematically illustrate the steps for fabricating a semiconductor device according to one embodiment of the present invention.

In FIG. 2A, the method for fabricating the semiconductor device, for example, first provides a substrate 200. The substrate 200 includes a memory cell region 203 and a peripheral circuit region 205. A dielectric layer 210, a conductive layer 220 and a mask layer 223 are formed on the substrate 200 in sequence. Herein, the substrate 200 is, for example, a silicon substrate. The material of the dielectric layer 210 is, for example, silicon oxide, and the method for fabricating the same is, for instance, a thermal oxidation process or a chemical vapor deposition process. The material of the conductive layer 220 is, for example, amorphous silicon, and the method for fabricating the same is, for example, a chemical vapor deposition process. The material of the mask layer 223 is, for example, silicon nitride, silicon carbide, or silicon carbon nitride, and the method for fabricating the same is, for example, a chemical vapor deposition. In one embodiment, the thickness of the conductive layer 220 is, for example, 200 Å, and the thickness of the mask layer 223 is, for example, 850 Å.

In FIG. 2A, portions of the mask layer 223, the conductive layer 220, the dielectric layer 210 and the substrate 200 are removed to form a plurality of trenches 225. The method for removing these layers includes, for example, the following steps. First, a patterned photoresist layer (not shown) is formed on the mask layer 223. Next, the exposed mask layer 223 and the conductive layer 220, the dielectric layer 210 and the substrate 200 underneath the exposed mask layer 223 are removed by performing a reactive ion etching process using the patterned photoresist layer as a mask. Afterward, the patterned photoresist layer is removed to form the trenches 225.

Thereafter, an insulating material is filled into the trenches 225 to form the isolation structures 230. The method for fabricating the isolation structures 230 includes, for example, the following steps. First, a layer of insulating material is deposited over the substrate 200. The insulating material is, for example, silicon oxide, and the method for depositing the insulating material is, for example, a high-density plasma chemical vapor deposition. Certainly, the insulating material just deposited will cover the mask layer 223. Therefore, the mask layer 223 is used as a stop layer when the insulating material is planarized so as to form the isolation structure 230 with a flat surface. The method for planarizing the insulating material is, for example, a chemical mechanical polishing process or an etch back process. Since the device layout for a memory cell region 203 is different from that for a peripheral circuit region 205, the isolation structures 230 in the memory cell region 203 will be denser than that in the peripheral region 205. In other words, the distance between the isolation structures 230 in the peripheral circuit region 205 will be greater than that in the memory cell region 203 as shown in FIG. 2A.

In FIG. 2B, a protective layer 240 is formed over the substrate 200. The material of the protective layer 240 is, for example, a conductor material, such as polysilicon, and the method for fabricating the same is, for example, a chemical vapor deposition process. A patterned photoresist layer 245 is formed on the protective layer 240 in the peripheral circuit region 205. The method for fabricating the patterned photoresist layer includes, for example, the following steps. First, a positive photoresist layer is formed on the protective layer 240. Then, an exposure process and a development process are performed to pattern and form the patterned photoresist layer 245.

In FIG. 2C, the protective layer 240 and the mask layer 223 in the memory cell region 203 are removed using the patterned photoresist layer 245 as a mask. The method for removing the protective layer 240 and the mask layer 223 in the memory cell region 203 is, for example, a wet etching process. Next, the patterned photoresist layer 245 is removed using a method such as a dry photoresist stripping process or a wet photoresist stripping process.

In FIG. 2D, a conductive layer 250 is formed over the substrate 200. The material of the conductive layer 250 is, for example, doped polysilicon, and the method for fabricating the same involves forming a layer of undoped polysilicon by a chemical vapor deposition process and then performing an ion-implantation process, or adopting an in-situ implantation in a chemical vapor deposition process. It should be noted that, the material of the protective layer 240 can vary according to the material used for fabricating the conductive layer 250. In general, the material of the protective layer 240 chosen is a conductor material that has approximately the same etching selectivity as the material used for fabricating the conductive layer 250.

In FIG. 2E, a portion of the conductive layer 250 and the protective layer 240 are removed using the isolation structure 230 as a stop layer. The method for removing the conductive layer 250 and the protective layer 240 is, for example, a chemical mechanical polishing process. Since the conductive layer 250 and the protective layer 240 have approximately the same etching selectivity, a chemical mechanical polishing process can be used to remove both layers. In the peripheral circuit region 205, both the isolation structure 230 and the mask layer 223 act as a stop layer. Next, the mask layer 223 in the peripheral circuit region 205 is removed, and the method for removing the same is, for example, a wet etching process. In one embodiment, the conductive layer 250 and the underlying conductive layer 220 are, for example, used as the floating gate of the memory cell.

In FIG. 2F, portions of the isolation structures 230 are removed to expose the sidewalls of the conductive layer 250. The method for removing the isolation structures 230 is, for example, a wet etching process. Then, a dielectric layer 270 and a conductive layer 280 are sequentially formed over the substrate 200. The dielectric layer 270 is, for example, silicon oxide-silicon nitride-silicon oxide, and the method for fabricating the same is, for example, a chemical vapor deposition process. Further, the material of the dielectric layer 270 can be other suitable dielectric material such as silicon oxide, silicon nitride or silicon oxide-silicon nitride. The materials for fabricating the conductive layer 280 include conductor materials such as doped polysilicon, metal or metal silicide, and the method for fabricating the same is, for example, a chemical vapor deposition process or a physical vapor deposition process. Herein, the dielectric layer 270 is, for example, used as the inter-gate dielectric layer of the memory cell, and the conductive layer is, for example, used as the control gate of the memory cell. The subsequent steps for fabricating the memory cell and other logic devices are well known to those skilled in the art. Therefore, the detailed description thereof is omitted.

Accordingly, the present embodiment first forms a protective layer 240 in the peripheral circuit region 205, covering the underlying mask layer 223 and the conductive layer 220. Next, a conductive layer 250 is formed. As a result, the conductive layer 250 will not be formed directly on the conductive layer 220 in the peripheral circuit region 205, which prevents the formation of device having sharp corners and effectively improves the uniformity of the thin film over the surface of a wafer.

According to the above-mentioned method, the etching process for the conductive layer 250 in the memory cell region 203 can be better controlled. Therefore, it will not be necessary to perform pattern design using a dummy rule for ameliorating the effects caused by sharp corners of the peripheral circuit region 205.

It should be noted that the present invention is not limited to the aforementioned embodiment which uses a memory cell region and a peripheral circuit region for illustration. The present invention can be applied in cases that involve isolation structures having two different pattern densities and desire improved uniformity of the thin film over the surface of a wafer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a semiconductor device, comprising:
providing a substrate that includes a memory cell region and a peripheral circuit region, wherein a first dielectric layer, a first conductive layer and a mask layer are formed on the substrate, a plurality of isolation structures are formed in the mask layer, the first dielectric layer and the substrate, and the isolation structures in the memory cell region are denser than that in the peripheral circuit region;
forming a protective layer over the substrate in the peripheral circuit region;
removing the mask layer in the memory cell region;
forming a second conductive layer over the substrate, wherein the second conductive layer and the protective layer have approximately the same etching selectivity;
removing a portion of the second conductive layer and the protective layer using the isolation structure as a stop layer;
removing portions of the isolation structures;
removing the mask layer in the peripheral circuit region; and
forming a second dielectric layer and a third conductive layer over the substrate sequentially.

2. The method of claim 1, wherein the steps for forming the protective layer over the substrate in the peripheral circuit region comprise:
forming a conformal protective material layer over the substrate;
forming a patterned photoresist layer on the protective material layer in the peripheral circuit region; and
removing the protective material layer in the memory cell region using the patterned photoresist layer as a mask.

3. The method of claim 2, further comprising removing the mask layer in the memory cell region using the patterned photoresist layer as a mask.

4. The method of claim 1, wherein the material of the protective layer and the second conductive layer comprises polysilicon.

5. The method of claim 1, wherein the method for removing a portion of the second conductive layer and the protective layer comprises a chemical mechanical polishing process using the isolation structures as a stop layer.

6. The method of claim 1, wherein the method for removing portions of the isolation structures comprises a wet etching process.

7. The method of claim 1, wherein the second dielectric layer comprises silicon oxide-silicon nitride-silicon oxide.

8. The method of claim 1, wherein the material of the first dielectric layer comprises silicon oxide.

9. The method of claim 1, wherein the material of the mask layer comprises silicon nitride.

10. The method of claim 1, wherein the of fabricating the third conductive layer comprises doped polysilicon.

11. The method of claim 1, after a portion of the second conductive layer and the protective layer are removed, the surface of the first conductive layer in the peripheral circuit region is maintained to be flat.

12. A method for improving thin film uniformity suitable for a substrate having a first region and a second region wherein a dielectric layer, a first conductive layer and a mask layer are formed on the substrate, a plurality of isolation structures are formed in the mask layer, the dielectric layer and the substrate, and the isolation structures in the first region are denser than that in the second region, comprising:
forming a protective layer over the substrate;
removing the protective layer and the mask layer in the first region;
forming a second conductive layer over the substrate, wherein the second conductive layer and the protective layer have approximately the same etching selectivity;
removing a portion of the second conductive layer and the protective layer using the isolation structures as a stop layer;
removing portions of the isolation structures; and
removing the mask layer in the second region, wherein the surface of first conductive layer in the second region is maintained to be flat.

13. The method of claim 12, wherein the steps for removing the protective layer in the first region and the mask layer comprises:
forming a patterned photoresist layer on the protective layer in the second region; and
removing the protective layer and the mask layer in the first region using the patterned photoresist layer as a mask.

14. The method of claim 12, wherein the material of the protective layer and the second conductive layer comprises polysilicon.

15. The method of claim 12, wherein the method for removing a portion of the second conductive layer and the protective layer comprises a chemical mechanical polishing process using the isolation structures as a stop layer.

16. The method of claim 12, wherein the method for removing portions of the isolation structures comprises a wet etching process.

17. The method of claim 12, wherein the material of the dielectric layer comprises silicon oxide.

18. The method of claim 12, wherein the material of the mask layer comprises silicon nitride.
